(19) United States
(12) Patent Application Publication
(10) Pub. No.: US 2015/0218690 A1
(43) Pub. Date: Aug. 6, 2015

(54) Vacuum Vapor Deposition Apparatus and Method

(71) Applicant: Shenzhen China Star Optoelectronics Technology Co., Ltd., Shenzhen, Guangdong (CN)

(72) Inventor: Youyuan Kuang, Shenzhen (CN)

(73) Assignee: Shenzhen China Star Optoelectronics Technology Co., Ltd., Shenzhen, Guangdong (CN)

(21) Appl. No.: 14/239,121

(22) PCT Filed: Jan. 9, 2014
(86) PCT No.: PCT/CN2014/070409

§ 371 Date: Feb. 14, 2014

(30) Foreign Application Priority Data
Dec. 30, 2013 (CN) 201310743673.1

(51) Int. Cl. C23C 14/24; C23C 14/04

(52) U.S. Cl. CPC C23C 14/24; C23C 14/042

(57) ABSTRACT

The present invention provides a vacuum vapor deposition apparatus, comprising a vacuum chamber, a vapor deposition source disposed in the vacuum chamber, and a positioning unit arranged above the vapor deposition source; wherein the vapor deposition source includes a heating container and a heating unit; wherein the heating container includes a material container, a steam vessel, and an output unit successively arranged from bottom to top; wherein a first partition disposed between the material container and the steam vessel defines a first vent; wherein a second partition disposed between the steam vessel and the output unit defines a second vent; and wherein the caliber of the first vent is larger than the second vent.

### FIELD OF THE INVENTION

The present invention relates to a technical field of display, and more particularly to a vacuum vapor deposition apparatus and method thereof.

### BACKGROUND OF THE INVENTION

A flat panel display has many advantages including thin, compact, energy-saving, no radiation, and so on, as a result, it has been widely used in different applications. The flat panel display available in the market today mainly includes a liquid crystal display (LCD) and an organic light emitting display (OLED) device.

Liquid crystal displays available in the market today are typically referred to as backlit liquid crystal display, which includes housings, a liquid crystal display panel disposed therein and a backlight module associated with the display panel. The working principle of the liquid crystal display panel is that the liquid crystal molecules are placed between two parallel glass substrates, and the alignment of the liquid crystal molecules is controlled by applying driving voltage to the glass substrate, so as to generate the image by refracting the light beam from the backlight module through the liquid crystal display panel.

The organic light emitting display device is different from a traditional liquid crystal display device, because it does not need a backlight, and a very thin coating of organic materials is directly deposited onto a glass substrate instead, so the coating of organic materials will be lit on when a current applied thereto. Accordingly, the organic light emitting display device features self-light emitting, high brightness, wide viewing angle, high contrast, flexibility, and low power consumption. Currently, the organic light emitting display device receives widespread attention, and has gradually replaced the traditional liquid crystal display device, as a result, it has been widely used in mobile phone screen, computer monitor, full-color television and other fields.

In the manufacturing process of the organic light emitting panel, an organic light emitting layer needs to be formed on the substrate, which means an organic light emitting diode has to be grown on the substrate. Currently, the organic light emitting diode has been mainly grown by heating vapor deposition. Referring to FIG. 1, which is a structural and illustrational view of a prior art vacuum vapor deposition apparatus, comprises a vacuum chamber, a vapor deposition source 30 disposed in the vacuum chamber, and a positioning plate 210 arranged above the vapor deposition source. Wherein the vapor deposition source 30 includes a material container 310 and a heating unit 320 deposited outside of the material container 310. In the manufacturing process of the organic light emitting panel, a substrate 220 and a mask 230 are successively arranged below of the positioning plate 210, and the side of the substrate 220 where the vapor deposition material will be deposited is arranged to face the vapor deposition source 30, wherein the positioning plate 210 is used for positioning the substrate 220 and the mask 230, and also for dissipating heat generated from the substrate 220. The heating unit 320 heats the material container 310 such that vapor of the vapor deposition material inside the material container 310 enters the steam vessel, and the vapor of the vapor deposition material passes through openings of the mask 230 and then deposits onto the substrate 220. However, in the process of deposition, the vapor of the vapor deposition material spreads in all directions after passing from the material container 310, and the maximal spray angle can up to 180 degrees, but the area of the substrate 220 is limited, so the vapor spread outside of the substrate 220 becomes a waste, and thereby reduces the utilization of materials and increases the manufacturing costs.

### SUMMARY OF THE INVENTION

In order to resolve the technical issue encountered by the prior art, the object of the present invention is to provide a vacuum vapor deposition apparatus, which reduces the loss of material deposited onto the unnecessary area except the substrate by controlling the spray angular range of the vapor of the vapor deposition material, and thereby improves the utilization of materials and reduces the manufacturing costs.

In order to achieve the above objects, the present invention provides a vacuum vapor deposition apparatus, comprising a vacuum chamber, a vapor deposition source disposed in the vacuum chamber, and a positioning unit arranged above the vapor deposition source; wherein the vapor deposition source includes a heating container and a heating unit; wherein the heating container includes a material container, a steam vessel, and an output unit successively arranged from bottom to top; wherein a first partition disposed between the material container and the steam vessel defines a first vent; wherein a second partition disposed between the steam vessel and the output unit defines a second vent; and wherein the caliber of the first vent is larger than the second vent.

Wherein the heating unit is deposited outside of the material container and the steam vessel for heating the material container and the steam vessel.

Wherein the output unit has a smooth inner wall.

Wherein the heating container includes one output unit.

Wherein the heating container includes a plurality of output units.

Wherein the plurality of output units are arranged linearly.

Wherein the plurality of output units are arranged in a planar form.

Wherein the vacuum vapor deposition apparatus includes a driving mechanism for displacing the vapor deposition source or the positioning unit.

The second object of the present invention is to provide a vacuum vapor deposition method, which is performed with the vacuum vapor deposition apparatus as described above, includes steps of: providing a substrate and a mask in which the substrate is disposed under the positioning unit, and the mask is right under the substrate; heating the heating container with the heating unit such that vapor of the vapor deposition material enters the steam vessel; and spraying the vapor of the vapor deposition material from the output unit to pass through openings of the mask and then deposit onto the substrate.

Wherein the heating unit is deposited outside of the material container and the steam vessel for heating the material container and the steam vessel.

Wherein the output unit has a smooth inner wall.

Wherein the heating container includes one output unit.

Wherein the heating container includes a plurality of output units.

Wherein the plurality of output units are arranged linearly.

Wherein the plurality of output units are arranged in a planar form.

Wherein the vacuum vapor deposition apparatus includes a driving mechanism for displacing the vapor deposition source or the positioning unit.

The vacuum vapor deposition apparatus provided by the present invention reduces the loss of material deposited onto the unnecessary area except the substrate by limiting the displacement path of the vapor of the vapor deposition material and controlling the spray angular range of the vapor of the vapor deposition material, and thereby improves the utilization of materials and reduces the manufacturing costs. At the same time, the vacuum vapor deposition apparatus provided by the present invention expands one output unit to a plurality of output units, and the plurality of output units are arranged linearly or in a planar form, so the uniformity of the vapor deposition material deposited onto the substrate is simultaneously improved, and the deposition rate is increased, and the manufacturing cost is further reduced.

### BRIEF DESCRIPTION OF DRAWINGS

FIG. 1 is a structural and illustrational view of a prior art vacuum vapor deposition apparatus.

FIG. 2 is a structural and illustrational view of a first embodiment of a vacuum vapor deposition apparatus made in accordance with the present invention.

FIG. 3 is a structural and illustrational view of a second embodiment of a vacuum vapor deposition apparatus made in accordance with the present invention.

FIG. 4 is a vertical view of a second embodiment of a vapor deposition source made in accordance with the present invention.

FIG. 5 is a structural and illustrational view of a third embodiment of a vacuum vapor deposition apparatus made in accordance with the present invention.

FIG. 6 is a vertical view of a third embodiment of a vapor deposition source made in accordance with the present invention.

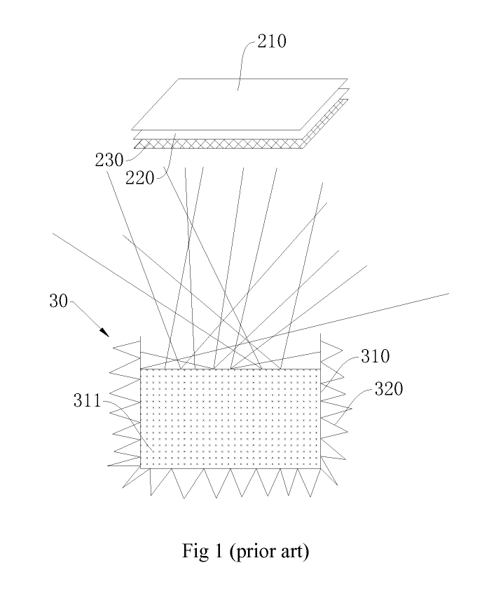

### DETAILED DESCRIPTION OF PREFERRED EMBODIMENTS

Now, a detailed description will be given with respect to preferred embodiments provided and illustrated here below with accompanied drawings. The legends are shown in the accompanied drawings, wherein the same legends always indicate the same or the substantially identical parts. In order to give a better and thorough understanding to the whole and other intended purposes, features and advantages of the present invention or the technical solution of the prior art, detailed description will be given with respect to preferred embodiments provided and illustrated here below in accompanied drawings.

### Embodiment I

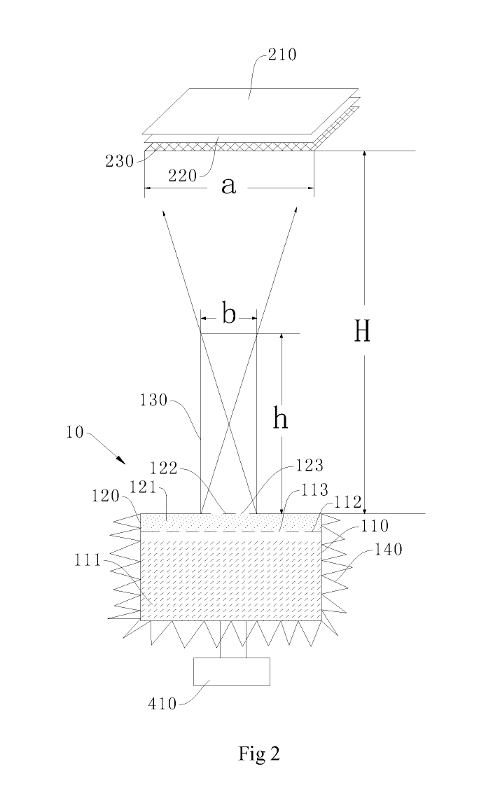

Referring to FIG. 2, which is a vacuum vapor deposition apparatus provided by the present embodiment, and which comprises a vacuum chamber, a vapor deposition source 10 disposed in the vacuum chamber, and a positioning unit arranged above the vapor deposition source 10, and in this embodiment, the positioning unit is a positioning plate 210, wherein the positioning plate 210 is used for positioning and dissipating heat generated from the substrate 220 and the mask 230 which are sequentially placed thereon. Wherein the vapor deposition source 10 includes a heating container and a heating unit 140; wherein the heating container includes a material container 110, a steam vessel 120, and an output unit 130 successively arranged from bottom to top; wherein the heating unit 140 is deposited outside of the material container 110 and the steam vessel 120 for heating the material container 110 and the steam vessel 120. In order to improve the uniformity of heating the material container 110 and the steam vessel 120, in this embodiment, the heating unit 140 is a heater surrounding the side wall of the material container 110 and the steam vessel 120, and the bottom of the material container 110. Of course, the circulation hot fluid may also be used for heating in other embodiments.

The bottom of the steam vessel 120 is in fact the top of the material container 110, and a first partition 112 disposed between the material container 110 and the steam vessel 120 defines a first vent 113; and wherein the bottom of the output unit 130 is also in fact the top of the steam vessel 120, and a second partition 122 disposed between the steam vessel 120 and the output unit 130 defines a second vent 123. After the heating unit 140 heats the material container 110 and the steam vessel 120, a vapor deposition material 111 in the material container 110 starts evaporating into a material vapor 121 which passes through the first vent 113, enters the steam vessel 120, passes through the second vent 123, and then spreads to the output unit 130 from the steam vessel 120. The caliber of the first vent 113 should be larger than the second vent 123, which means in the very beginning, the material vapor 121 entering to the steam vessel 120 is more than the material vapor 121 spraying from the steam vessel 120, and then the saturated vapor pressure can be reached in the steam vessel 120 after accumulating in a certain period of time, so by this arrangement, the traveling speed of the material vapor 121 is ensured enough after entering the output unit 130, and thereby the material vapor 121 can smoothly spray from the output unit 130 to pass through openings of a mask 230 and then deposit onto the substrate 220.

Furthermore, the diameter of the output unit 130 is smaller than the diameter of the steam vessel 120 and the material container 110, which means that the first partition 112 is larger than the second partition 122. Meanwhile, the output unit 130 has a certain height and a smooth inner wall. The material vapor 121 accumulates in the steam vessel 120, and the material vapor 121 spreads from the second vent 123 to the output unit 130 after the saturated vapor pressure is reached in the steam vessel 120. Because the output unit 130 is in a non-heated state and the output unit 130 has a certain height, only some material vapor 121 with an appropriate angle and enough traveling speed can spray from the output unit 130 to deposit onto the substrate 220, and the material vapor 121 with a wrong angle or insufficient traveling speed will be condensed into the vapor deposition material 111 by the inner wall of the output unit 130, and flows back into the material container 110 to recycle. Therefore, if the substrate is placed in a suitable position, the utilization of the vapor deposition material 111 can be pushed to a full extent. To better understand the working principle of the present invention, a typical structure of a cylindrical shape will be used as an example to describe in the present embodiment. The diameter of the output unit 130 is b; the height is h; the horizontal width of the substrate 220 is a; and the height difference between the substrate 220 and the output unit 130 is H, wherein a is the minimal angle of the material vapor allowed to spray. Therefore, the height difference between the substrate 220 and the output unit 130 is H=h(a+b)/2b, and the minimal angle of the material vapor allowed to spray is a=arctan(h/b).

Furthermore, the vacuum vapor deposition apparatus provided by the present embodiment further includes a rotational driving mechanism 410 arranged below of the vapor deposition source 10 for creating a rotational movement of the vapor deposition source 10. The vapor deposition source 10 of the vacuum vapor deposition apparatus provided by the present embodiment includes the output unit 130, and the vapor deposition source 10 is a point source. The vapor deposition source 10 has a rotational movement which is driven by the rotational driving mechanism 410, so the material vapor 121 will be distributed more evenly below the substrate 220 in the vacuum chamber after spraying from the output unit 130, and thereby the material vapor deposits onto the substrate 220 uniformly. Of course, in other embodiments, the rotational driving mechanism 410 also can be placed above the positioning plate 210 for displacing the positioning plate 210, or it may be a driving mechanism for others.

Based on the same inventive concept, the present embodiment further provides a vacuum vapor deposition method, which is performed with the vacuum vapor deposition apparatus as described above, which includes the steps of: providing the substrate 220 and the mask 230 in which the substrate 220 is disposed right under the positioning plate 210; the side of the substrate 220 where the vapor deposition material will be deposited is arranged to face the vapor deposition source 10; the mask 230 is right under the substrate 220; the vapor deposition material 111 is provided in the material container 110; the heating unit 140 heats the material container 110 and the steam vessel 112 such that the vapor deposition material 111 in the material container 110 starts evaporating into a material vapor 121 which passes through the first vent 113, enters the steam vessel 120; the material vapor 121 accumulates in the steam vessel 120, and the material vapor 121 spreads to the output unit 130 after the saturated vapor pressure is reached; the material vapor 121 with a spray angle greater than a=arctan(h/b) and enough traveling speed spreads from the output unit 130, passes through the opening of the mask 230, and then deposits onto the substrate 220; and the other material vapor 121 will be condensed into the vapor deposition material 111 by the inner wall of the output unit 130, and flows back into the material container 110.

The vacuum vapor deposition apparatus provided by the present embodiment reduces the loss of material deposited onto the unnecessary area except the substrate by limiting the displacement path of the material vapor and controlling the spray angular range of the material vapor, and thereby improves the utilization of materials and reduces the manufacturing costs.

### Embodiment II

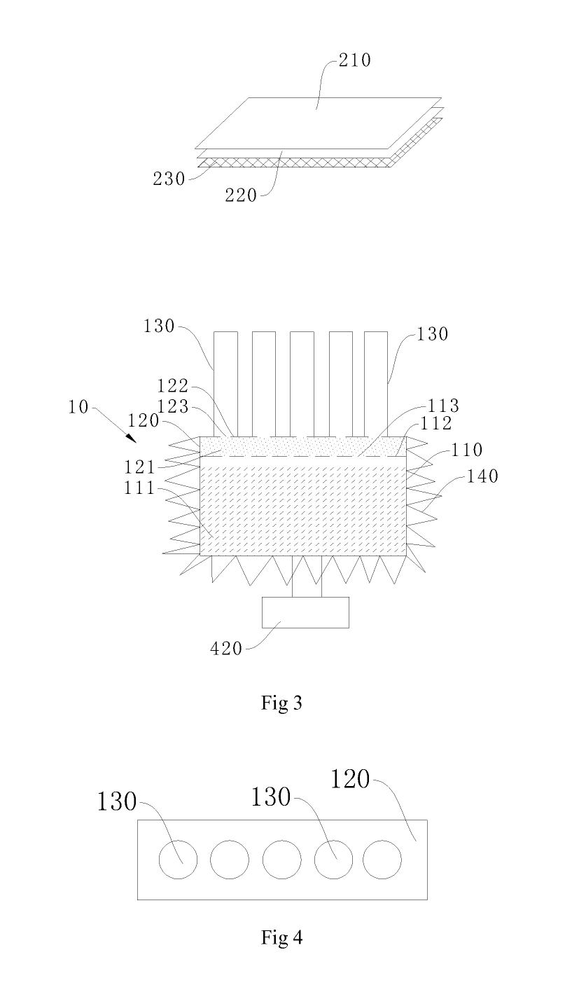

Referring to FIG. 3 and FIG. 4, which is a vacuum vapor deposition apparatus provided by the present embodiment, and which comprises a vacuum chamber, a vapor deposition source 10 disposed in the vacuum chamber, and a positioning unit arranged above the vapor deposition source 10, and in this embodiment, the positioning unit is a positioning plate 210, wherein the positioning plate 210 is used for positioning and dissipating heat generated from the substrate 220 and the mask 230 which are sequentially placed thereon. Wherein the vapor deposition source 10 includes a heating container and a heating unit 140; wherein the heating container includes a material container 110, a steam vessel 120, and an output unit 130 successively arranged from bottom to top; wherein the heating unit 140 is deposited outside of the material container 110 and the steam vessel 120 for heating the material container 110 and the steam vessel 120. The top of the material container 110 is in fact the bottom of the steam vessel 120, and a first partition 112 disposed between the material container 110 and the steam vessel 120 defines a first vent 113; and wherein the bottom of the output unit 130 is also in fact the top of the steam vessel 120, and a second partition 122 disposed between the steam vessel 120 and the output unit 130 defines a second vent 123.

The difference from the first embodiment is that the steam vessel 120 of the vacuum vapor deposition apparatus provided by the present invention includes the plurality of output units 130 arranged linearly, and the vapor deposition source 10 is a point source, wherein the total caliber of the second vent 123 is smaller than the first vent 113. Therefore, the uniformity of the vapor deposition material deposited onto the substrate is improved, and the deposition rate is simultaneously increased, and the manufacturing cost is further reduced. At this time, the height difference between the substrate 220 and the output unit 130 is H, and a is the minimal angle of the material vapor allowed to spray, which relates to the width of the substrate corresponding to a single output unit 130 rather than the width of the whole substrate, and the specific relationship refers to the first embodiment.

Furthermore, the vacuum vapor deposition apparatus provided by the present embodiment further includes a horizontal driving mechanism 420 arranged below of the vapor deposition source 10 for creating a horizontal movement of the vapor deposition source 10. The vapor deposition source 10 of the vacuum vapor deposition apparatus provided by the present embodiment is a point source, and the vapor deposition source 10 has a horizontal reciprocal movement which is driven by the horizontal driving mechanism 420 and the direction of the motion is vertical to the arrangement of the output unit 130, so the material vapor 121 can be distributed more evenly below the substrate 220 in the vacuum chamber after spraying from the output unit 130, and thereby the material vapor deposits onto the substrate 220 uniformly. Of course, in other embodiments, the horizontal driving mechanism 420 also can be placed above the positioning plate 210 for displacing the positioning plate 210, or it may be a driving mechanism for others.

### Embodiment III

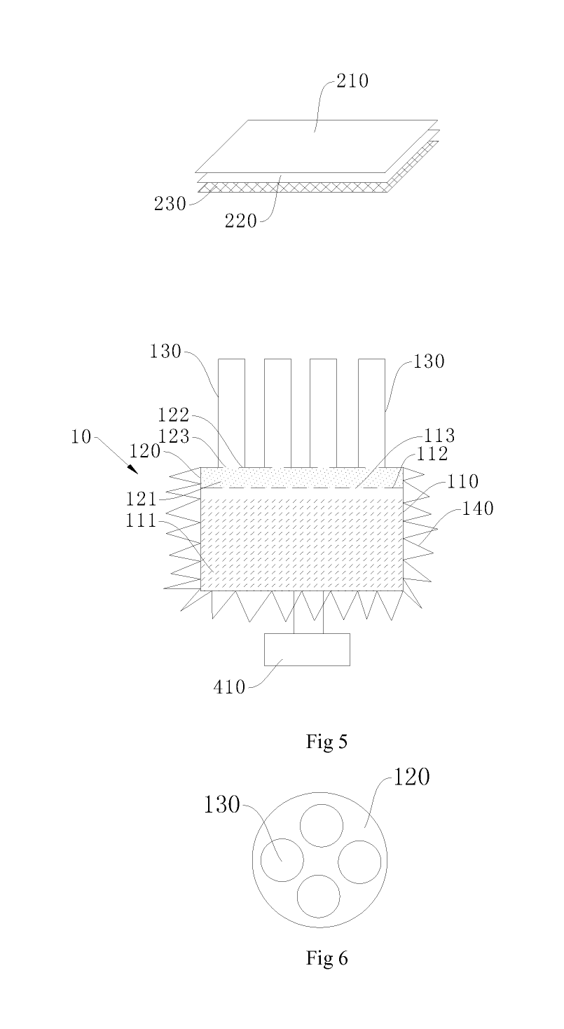

Referring to FIG. 5 and FIG. 6, which is a vacuum vapor deposition apparatus provided by the present embodiment, and which comprises a vacuum chamber, a vapor deposition source 10 disposed in the vacuum chamber, and a positioning unit arranged above the vapor deposition source 10, and in this embodiment, the positioning unit is a positioning plate 210, wherein the positioning plate 210 is used for positioning and dissipating heat generated from the substrate 220 and the mask 230 which are sequentially placed thereon. Wherein the vapor deposition source 10 includes a heating container and a heating unit 140; wherein the heating container includes a material container 110, a steam vessel 120, and an output unit 130 successively arranged from bottom to top; wherein the heating unit 140 is deposited outside of the material container 110 and the steam vessel 120 for heating the material container 110 and the steam vessel 120. The top of the material container 110 is in fact the bottom of the steam vessel 120, and a first partition 112 disposed between the material container 110 and the steam vessel 120 defines a first vent 113; and wherein the bottom of the output unit 130 is also in fact the top of the steam vessel 120, and a second partition 122 disposed between the steam vessel 120 and the output unit 130 defines a second vent 123.

The difference from the second embodiment is that the vapor deposition source 10 including the steam vessel 120 includes the plurality of output units 130 arranged in a planar form, and the vapor deposition source 10 is a planar source, wherein the total caliber of the second vent 123 is smaller than the first vent 113. Furthermore, the vacuum vapor deposition apparatus provided by the present embodiment further includes a rotational driving mechanism 410 arranged below of the vapor deposition source 10 for creating a rotational movement of the vapor deposition source 10. The vapor deposition source 10 of the vacuum vapor deposition apparatus provided by the present embodiment is a planar source, and the vapor deposition source 10 has a rotational movement which is driven by the rotational driving mechanism 410, so the material vapor 121 can be distributed more evenly below the substrate 220 in the vacuum chamber after spraying from the output unit 130, and thereby the material vapor deposits onto the substrate 220 uniformly. Of course, in other embodiments, the rotational driving mechanism 410 also can be placed above the positioning plate 230 for displacing the positioning plate 230, or it may be a driving mechanism for others.

The vacuum vapor deposition apparatus provided by the present embodiment not only can improve the uniformity of the vapor deposition material deposited onto the substrate, but also the deposition rate is simultaneously increased, and the manufacturing cost is further reduced.

In conclusion, the vacuum vapor deposition apparatus provided by the present invention reduces the loss of material deposited onto the unnecessary area except the substrate by limiting the displacement path of the vapor of the vapor deposition material and controlling the spray angular range of the vapor of the vapor deposition material, and thereby improves the utilization of materials and reduces the manufacturing costs. At the same time, the vacuum vapor deposition apparatus provided by the present invention expands one output unit to a plurality of output units, and the plurality of output units are arranged linearly or in a planar form, so the uniformity of the vapor deposition material deposited onto the substrate is simultaneously improved, and the deposition rate is increased, and the manufacturing cost is further reduced.

It should be noted that, in this paper, such as the first and second terms of the type of relationship will only be used to operate with one entity or another entity or operate separate, but not necessarily required, or between these entities or operations imply the existence of any such actual relationship or order. Moreover, the term “comprising”, “including” or any other variants thereof are intended to cover a non-exclusive inclusion, such that a number of elements including the process, method, article, or device including not only those elements, but also not explicitly listed other elements, or also for such process, method, article, or those elements inherent device. In the case where no more restrictions, by the statement “includes a” qualified elements, including the said element does not exclude a process, method, article or device is also the same as the other elements present.

Although embodiments of the present invention have been described, persons of the skilled in the art should understand that any modification of equivalent structure or equivalent process without departing from the spirit and scope of the present invention limited by the claims is allowed.

1. A vacuum vapor deposition apparatus comprises a vacuum chamber, a vapor deposition source disposed in the vacuum chamber, and a positioning unit arranged above the vapor deposition source; wherein the vapor deposition source includes a heating container and a heating unit; wherein the heating container includes a material container, a steam vessel, and an output unit successively arranged from bottom to top; wherein a first partition disposed between the material container and the steam vessel defines a first vent; wherein a second partition disposed between the steam vessel and the output unit defines a second vent; and wherein the caliber of the first vent is larger than the second vent.

2. The vacuum vapor deposition apparatus as recited in claim 1, wherein the heating unit is deposited outside of the material container and the steam vessel for heating the material container and the steam vessel.

3. The vacuum vapor deposition apparatus as recited in claim 2, wherein the output unit has a smooth inner wall.

4. The vacuum vapor deposition apparatus as recited in claim 3, wherein the heating container includes one output unit.

5. The vacuum vapor deposition apparatus as recited in claim 3, wherein the heating container includes a plurality of output units.

6. The vacuum vapor deposition apparatus as recited in claim 1, wherein the heating container includes one output unit.

7. The vacuum vapor deposition apparatus as recited in claim 1, wherein the heating container includes a plurality of output units.

8. The vacuum vapor deposition apparatus as recited in claim 7, wherein the plurality of output units are arranged linearly.

9. The vacuum vapor deposition apparatus as recited in claim 7, wherein the plurality of output units are arranged in a planar form.

10. The vacuum vapor deposition apparatus as recited in claim 1, wherein the vacuum vapor deposition apparatus includes a driving mechanism for displacing the vapor deposition source or the positioning unit.

11. A vacuum vapor deposition method, which is performed with the vacuum vapor deposition apparatus as recited in claim 1, includes steps of:
providing a substrate and a mask in which the substrate is disposed under the positioning unit, and the mask is right under the substrate;
heating the heating container with the heating unit such that vapor of the vapor deposition material enters the steam vessel; and
spraying the vapor of the vapor deposition material from the output unit to pass through openings of the mask and then deposit onto the substrate.

12. The vacuum vapor deposition method as recited in claim 11, wherein the heating unit is deposited outside of the material container and the steam vessel for heating the material container and the steam vessel.

13. The vacuum vapor deposition method as recited in claim 12, wherein the output unit has a smooth inner wall.

14. The vacuum vapor deposition method as recited in claim 11, wherein the heating container includes one output unit.

15. The vacuum vapor deposition method as recited in claim 11, wherein the heating container includes a plurality of output units.

16. The vacuum vapor deposition method as recited in claim 15, wherein the plurality of output units are arranged linearly.

17. The vacuum vapor deposition method as recited in claim 15, wherein the plurality of output units are arranged in a planar form.

18. The vacuum vapor deposition method as recited in claim 11, wherein the vacuum vapor deposition apparatus includes a driving mechanism for displacing the vapor deposition source or the positioning unit.
